(19) United States
(12) Patent Application Publication
(10) Pub. No.: US 2025/0336797 A1
(43) Pub. Date: Oct. 30, 2025

(54) PACKAGES WITH POWER SWITCHES AND POWER USER CIRCUITS SEPARATED IN DIFFERENT DIES

(71) Applicant: Taiwan Semiconductor Manufacturing Co., Ltd., Hsinchu (TW)

(72) Inventors: Chih-Chao Chou, Hsinchu (TW); Cheng-Chi Chuang, New Taipei City (TW); Ching-Wei Tsai, Hsinchu (TW); Shang-Wen Chang, Jhubei City (TW)

(21) Appl. No.: 19/262,458

(22) Filed: Jul. 8, 2025

Related U.S. Application Data
(63) Continuation of application No. 18/495,495, filed on Oct. 26, 2023.
(60) Provisional application No. 63/517,381, filed on Aug. 3, 2023.

(51) Int. Cl. H01L 23/498; H01L 23/00; H01L 25/065

(52) U.S. Cl. CPC H01L 23/49838; H01L 23/49816; H01L 24/08; H01L 24/16; H01L 25/0657; H01L 2224/08146; H01L 2224/08221; H01L 2224/16146; H01L 2224/16227; H01L 2225/06513; H01L 2225/06541; H01L 2924/01022; H01L 2924/1306

(57) ABSTRACT

A method includes forming a first device die and a second device die. The first device die includes a first integrated circuit, and a first bond pad at a first surface of the first device die. The first integrated circuit is electrically connected to the first bond pad. The second device die includes a power switch that includes a first source/drain region, a second source/drain region, a second bond pad electrically connecting to the first source/drain region, and a third bond pad electrically connecting to the second source/drain region. The method further includes bonding the first device die with the second device die to form a package, with the first bond pad bonding to the third bond pad, and bonding the package to a package component.

### PRIORITY CLAIM AND CROSS-REFERENCE

This application is a continuation of U.S. patent application Ser. No. 18/495,495, filed Oct. 26, 2023, which application claims the benefit of the following provisionally filed U.S. Patent application: Application No. 63/517,381, filed on Aug. 3, 2023, and entitled “CHIPLET POWER SWITCHES,” which applications are hereby incorporated herein by reference.

### BACKGROUND

Header cells (power switches) are used in integrated circuits for gating the power provided to certain circuits. A header cell may include a transistor, whose source may be connected to a power node such as VDD. The drain may be used as another power node, whose voltage is determined by whether the transistor is turned on or off. When the header cell is turned on, the drain receives the power, and hence the circuit is powered. When the header cell is turned off, no power is provided to the circuit.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-5 illustrate the cross-sectional views of intermediate stages in the formation of a package including a power switch and a power user circuit separated into different dies in accordance with some embodiments.

FIGS. 6-11 illustrate the cross-sectional views of intermediate stages in the formation of a package including a power switch and a power user circuit separated into different dies in accordance with some embodiments.

FIGS. 12 and 13 illustrate the cross-sectional views of packages including power switches and respective power user circuits separated into different dies in accordance with some embodiments.

FIG. 14 illustrates a process flow for forming a package including a power switch and a power user circuit separated into different dies in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A package including a power switch and a power user circuit separated into different dies and the method of forming the same are provided. In accordance with some embodiments of the present disclosure, a first device die is formed to include a power switch, and a second device die is formed and includes a power user circuit. The first device die is bonded to the second device die, so that the power switch in the first device die provides and controls power to the power user circuit. By placing the power switch in the first device die rather than the second device die that includes the power user circuit of the power, the chip area of the second device die, which includes advanced circuits and thus is chip area demanding, is saved. Embodiments discussed herein are to provide examples to enable making or using the subject matter of this disclosure, and a person having ordinary skill in the art will readily understand modifications that can be made while remaining within contemplated scopes of different embodiments. Throughout the various views and illustrative embodiments, like reference numbers are used to designate like elements. Although method embodiments may be discussed as being performed in a particular order, other method embodiments may be performed in any logical order.

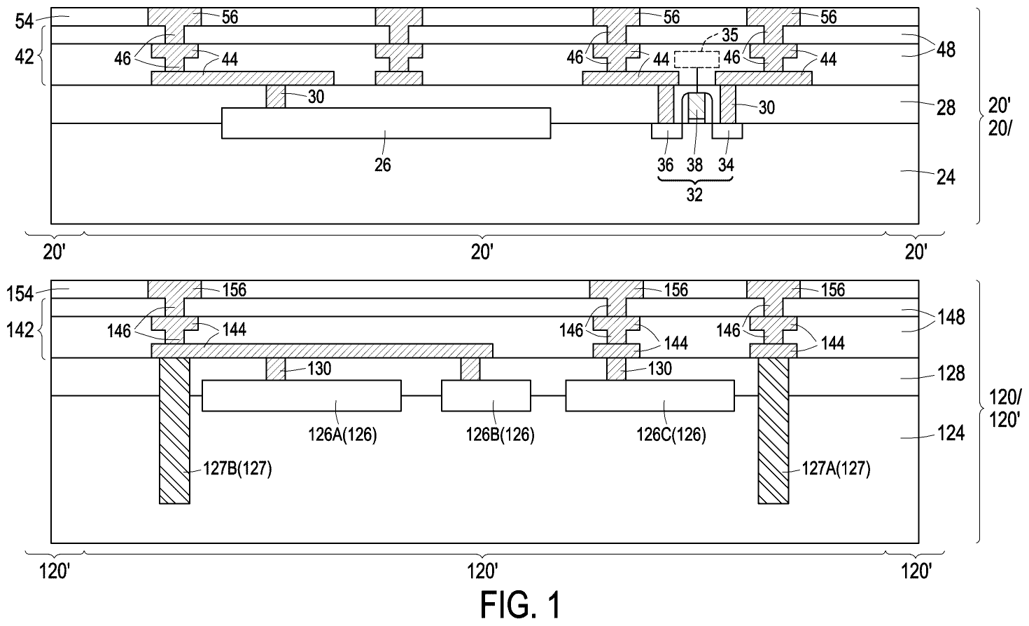

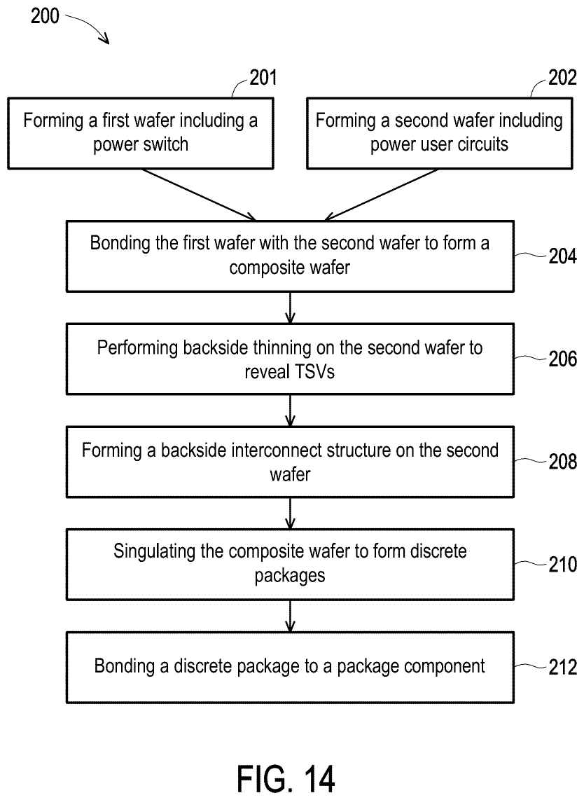

FIGS. 1 through 5 illustrate the cross-sectional views of intermediate stages in the formation of a package including a power switch and a power user circuit in accordance with some embodiments of the present disclosure. The corresponding processes are also reflected schematically in the process flow 200 as shown in FIG. 14.

FIG. 1 illustrates the formation of device wafer 20 in accordance with some embodiments. The respective process is illustrated as process 201 in the process flow 200 as shown in FIG. 14. Device wafer 120 is also formed. The respective process is illustrated as process 202 in the process flow 200 as shown in FIG. 14. Wafer 20 may include a plurality of device dies 20′ therein. Wafer 120 may include a plurality of device dies 120′ therein. In accordance with some embodiments, wafer 120 has circuits and design different from that of wafer 20. In accordance with some embodiments, wafer 20 includes Input/Output (IO) circuits, memory circuits (such as Dynamic Random-Access memory (DRAM) circuits, Static Random-Access memory (SRAM) circuits), or the like. Wafer 120 may include logic circuits such as a Central Processing Unit (CPU), a Graphic processing Unit (GPU), or the like.

In accordance with some embodiments, wafer 120 is manufactured using a more advanced (which may be newer) technology than wafer 20. For example, wafer 20 may be a non-advanced wafer formed of 10 nm technology or older, while wafer 120 may be an advanced wafer manufactured using 7 nm technology or newer. The critical dimensions (the widths of the gates of) of the transistors in wafer 120 are accordingly smaller than the critical dimensions of the transistors in wafer 20.

In accordance with some embodiments, wafer 20 includes semiconductor substrate 24 and the features formed at a top surface of semiconductor substrate 24. Semiconductor substrate 24 may be formed of or comprise crystalline silicon, crystalline germanium, crystalline silicon germanium, carbon-doped silicon, a III-V compound semiconductor, or the like. Semiconductor substrate 24 may also be a bulk semiconductor substrate or a Semiconductor-On-Insulator (SOI) substrate.

In accordance with some embodiments, wafer 20 includes integrated circuit devices 26, which are formed at the top surface of semiconductor substrate 24. Integrated circuit devices 26 may include Complementary Metal-Oxide Semiconductor (CMOS) transistors, resistors, capacitors, diodes, and/or the like in accordance with some embodiments. The details of integrated circuit devices 26 are not illustrated herein.

Inter-Layer Dielectric (ILD) 28 is formed over semiconductor substrate 24 and fills the spaces between the gate stacks of transistors (not shown) in integrated circuit devices 26. In accordance with some embodiments, ILD 28 is formed of Phospho Silicate Glass (PSG), Boro Silicate Glass (BSG), Boron-doped Phospho Silicate Glass (BPSG), Fluorine-doped Silicate Glass (FSG), silicon oxide, silicon oxynitride, silicon nitride, or the like. ILD 28 may be formed using spin-on coating, Flowable Chemical Vapor Deposition (FCVD), Chemical Vapor Deposition (CVD), or the like.

Contact plugs 30 are formed in ILD 28, and are used to electrically connect integrated circuit devices 26 to overlying metal lines 44 and vias 46. In accordance with some embodiments, contact plugs 30 are formed of or comprise a conductive material selected from tungsten, aluminum, copper, titanium, tantalum, titanium nitride, tantalum nitride, alloys thereof, and/or multi-layers thereof.

FIG. 1 further illustrates header cell 32 (alternatively referred to as a power switch) in accordance with some embodiments. Power switch 32 may include a transistor, which may include source region 34, drain region 36, and gate 38. Source region 34 and drain region 36 are collectively referred to as source/drain regions. Power switch 32 has the function of receiving a power (referred to as a True VDD (TVDD) on source region 34, which is alternatively referred to as a TVDD node. Drain region 36 is referred to a Virtual VDD (VVDD) node, which receives the power when power switch 32 is turned on, and is cut from the power when power switch 32 is turned off. The power on the VVDD node 36 is provided to a power user circuit in device die 120′, as will be discussed in subsequent paragraphs.

Interconnect structure 42 is formed over ILD 28 and contact plugs 30. Interconnect structure 42 may include metal lines 44 and vias 46, which are formed in dielectric layers 48 (also referred to as Inter-metal Dielectrics (IMDs)). The metal lines 44 at a same level are collectively referred to as a metal layer hereinafter. In accordance with some embodiments, interconnect structure 42 includes a plurality of metal layers interconnected through vias 46. Metal lines 44 and vias 46 may be formed of copper, a copper alloy, and/or another metal. In accordance with some embodiments, dielectric layers 48 are formed of low-k dielectric materials. The dielectric constants (k values) of the low-k dielectric materials may be lower than about 3.5 or lower than about 3.0, for example. Dielectric layers 48 may comprise a carbon-containing low-k dielectric material.

In accordance with some embodiments, the formation of metal lines 44 and vias 46 may include single damascene or dual damascene processes. In accordance with some embodiments, the formation of a bottom metal layer (including metal lines 44) may be performed through a single damascene process, which includes depositing a dielectric layer 48, etching the dielectric layer 48 to form trenches, filling the trenches with conductive materials, and then performing a planarization process such as a CMP process to remove excess portions of the conductive materials. The overlying metal lines and vias may be formed through dual damascene processes, which include forming dielectric layers, forming via openings and trenches in the dielectric layers, filling the via openings and the trenches with conductive materials, and performing planarization processes.

Over interconnect structure 42 may include a passivation layer(s) (not shown separately), which may be formed of a non-low-k dielectric material, over the low-k dielectric layers. The passivation layer may be formed of or comprise Undoped Silicate Glass (USG), silicon nitride, silicon oxide, or the like, or multi-layers thereof. There may also be metal pads (such as aluminum copper pads), Post Passivation Interconnect (PPI), or the like.

Over interconnect structure 42, bond film 54 is deposited. The top surface of bond film 54 is coplanar. In accordance with some embodiments, bond film 54 may be formed of a silicon-based dielectric material, which may be formed of or comprise SiON, SiN, SiOCN, SiCN, SiOC, SiC, or the like.

Bond pads 56 are formed in bond film 54 and electrically connecting to power switch 32 and integrated circuits 26. Bond pads 56 may have top surfaces coplanar with the top surface of bond film 54, which may be achieved through a planarization process. In accordance with some embodiments, bond pads 56 are formed in a damascene process, which include etching bond film 54 to form openings, filling the openings with a conductive material(s), and performing the planarization process.

FIG. 1 further illustrates the formation of wafer 120. In accordance with some embodiments, wafer 120 has similar layers as that of wafer 20. The structures and the materials of the features in wafer 120 may be found referring to the like features in wafer 20, with the like features in wafer 120 being denoted by adding number “1” in front of the reference numbers of the corresponding features in wafer 20. For example, the substrate in wafer 20 is denoted as 24, and accordingly, the substrate in wafer 120 is denoted as 124. Wafer 120 may include integrated circuit devices 126, ILD 128, contact plugs 130, interconnect structure 142, dielectric layers 148, metal lines 144, and vias 146. Wafer 120 further includes bond film 154 and bond pads 156 in bond film 154. The details of these features may be similar to the corresponding features in wafer 20, and are not repeated herein.

In accordance with some embodiments, wafer 120 includes integrated circuits 126 that further include active devices and passive devices therein to form the function circuits. Integrated circuits 126 may include integrated circuits 126A, integrated circuits 126B, and integrated circuits 126C. In accordance with some embodiments, the integrated circuits 126A, during its operation, constantly receives power (such as TVDD). Integrated circuits 126C, on the other hand, are the power user circuits receiving the gated voltage VVDD from device die 20′ as uses the power. Accordingly, depending on whether power switch 32 is turned on or off, integrated circuits 126C may be powered or not powered. Integrated circuits 126B may be a control circuit that provides control signal to control whether power switch 32 is turned on or off, and provides control signals to control whether the power user circuits 126C receives the power or not.

In accordance with some embodiments, through-vias 127 (alternatively referred to as Through-silicon-vias (TSVs) or through-Semiconductor-vias (also TSVs)) are formed in wafer 120. Through-vias 127 extend from the top surface to an intermediate level between the top surface and the bottom surface of semiconductor substrate 124. The top ends of through-vias 127 may extend to the top surface of ILD 128. Alternatively, the top ends of through-vias 127 may be at any available levels such as the top surface level of semiconductor substrate, or a top surface level of any one of dielectric layers 148.

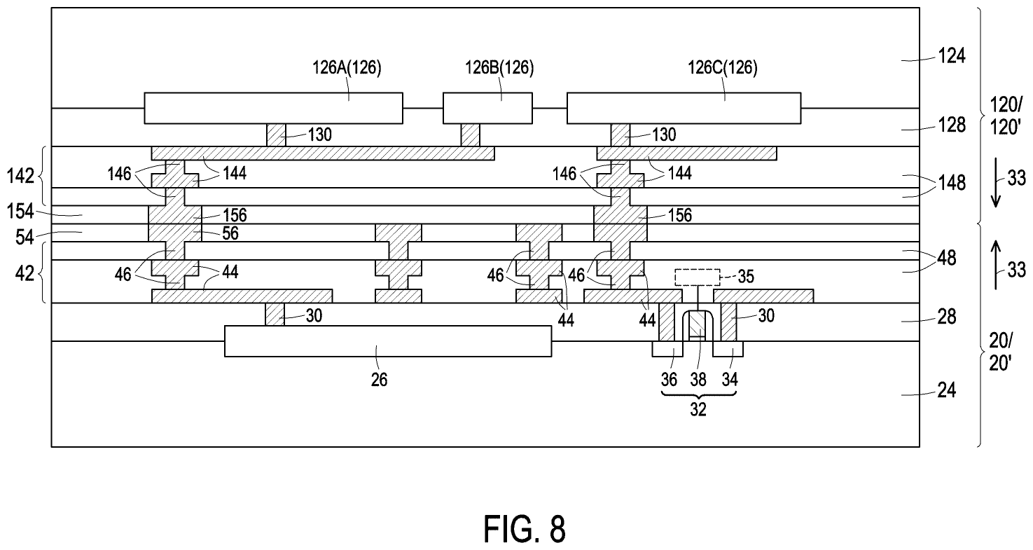

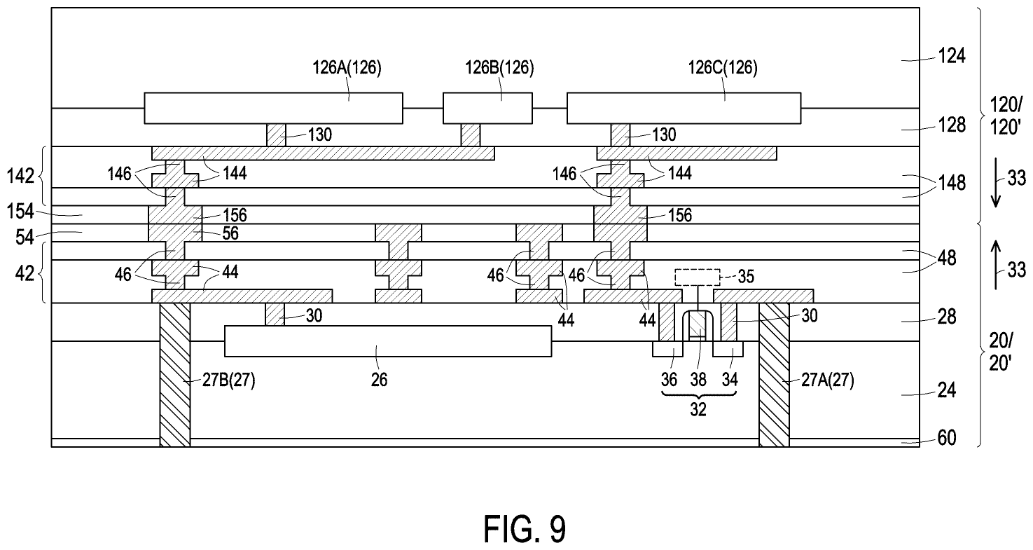

In accordance with some embodiments such as what is illustrated in FIGS. 1-4, the packaging process is a through-via-first process, in which through-vias 127 are formed before the bonding of wafer 20 with wafer 120. In accordance with alternative embodiments, a through-via-last process may be adopted to form through-vias 127, so that through-vias are formed after the wafer bonding process. An example through-via-last process is illustrated in FIGS. 8 and 9 in accordance with some embodiments.

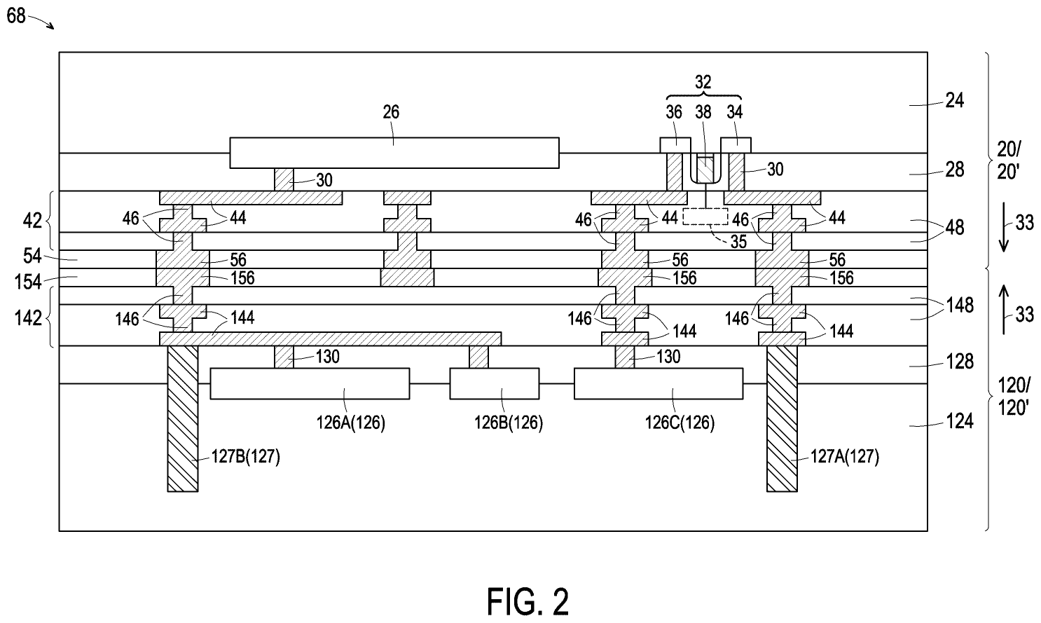

Referring to FIG. 2, wafer 20 is flipped upside down, and is bonded to wafer 120 to form composite wafer 68. The respective process is illustrated as process 204 in the process flow 200 as shown in FIG. 14. The bonding may be achieved through hybrid bonding, which includes the metal-to-metal direct bonding of bond pads 56 to bond pads 156, and the fusion bonding (with Si—O—Si bonds formed, for example) of bond film 54 to bond film 154. In accordance with alternative embodiments, wafers 20 and 120 may be bonded through solder bonding, metal-to-metal direct bonding (of metal bumps), or the like. In the illustrated example, the bonding is a face-to-face bonding, in which the front side (the face) of wafer 20 is bonded to the front side of wafer 120. The arrows 33 on the right side of FIG. 2 are shown as pointing to each other to represent the face-to-face bonding. The front side is the side of the respective semiconductor substrate having integrated circuits formed.

In accordance with some embodiments, wafer-on-wafer bonding is performed to bond wafer 20 to wafer 120, and accordingly, device die 20′ to device die 120′. In accordance with alternative embodiments, the bonding may be performed through die-on-wafer bonding, in which discrete dies 20′ are bonded to a wafer 120, or die-on-die bonding, in which a discrete die 20′ is bonded to a discrete die 120′.

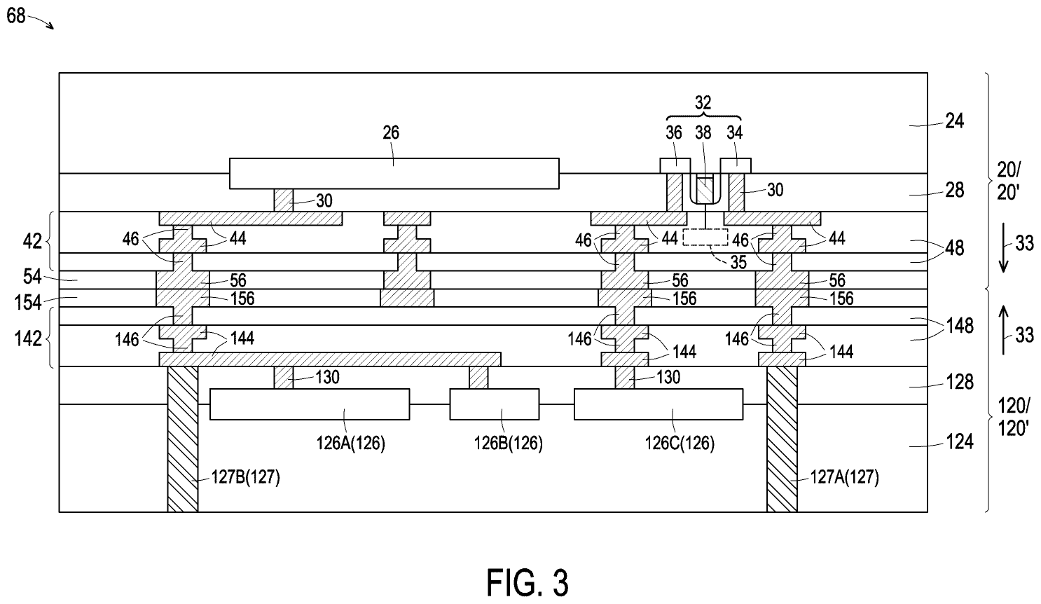

FIG. 3 illustrates a backside thinning process to thin semiconductor substrate 124 from its backside. The respective process is illustrated as process 206 in the process flow 200 as shown in FIG. 14. The backside thinning process may be performed through a Chemical Mechanical Polish (CMP) process or a mechanical grinding process. In accordance with some embodiments, the backside thinning process is stopped after through-vias 127 are exposed from the backside of semiconductor substrate 124.

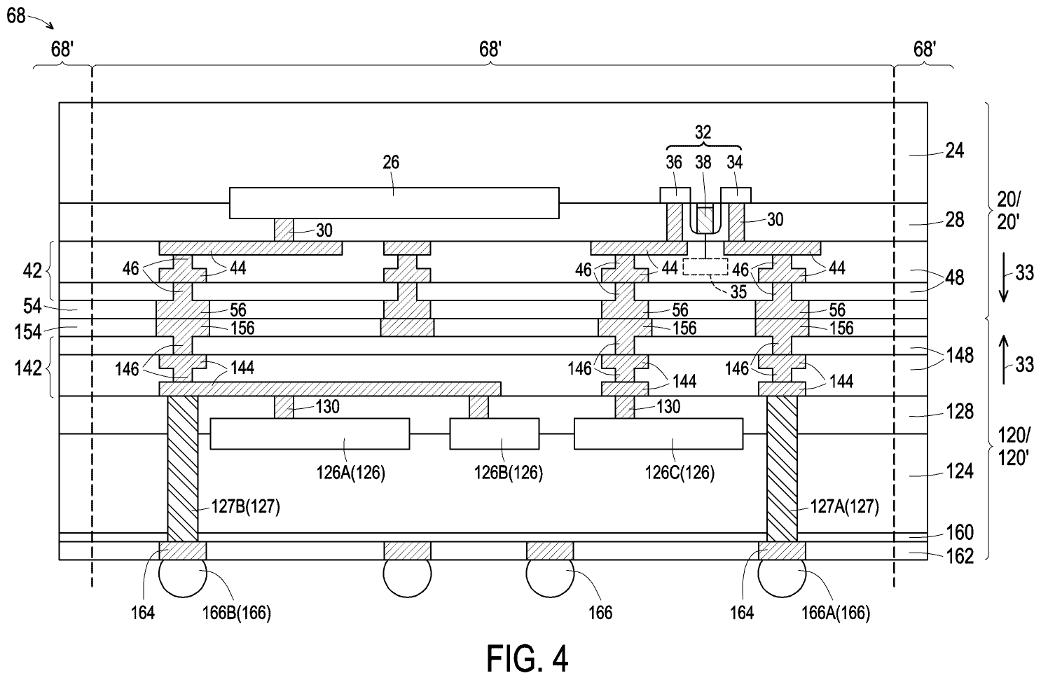

Next, semiconductor substrate 124 may be recessed from the backside, so that some end portions of through-vias 127 protrude out of semiconductor substrate 124, as shown in FIG. 4. Dielectric layer 160 is then formed to encircle and to be in contact with the protruding portions of through-vias 127, as also shown in FIG. 4. In accordance with some embodiments, the formation of dielectric layer 160 includes depositing a dielectric material such as silicon oxide, silicon nitride, silicon oxynitride, silicon oxy-carbo-nitride, or the like to embed the protruding portions of through-vias 127 therein. A light planarization process is then performed to remove excess portions of the dielectric layer and to reveal through-vias 127 again. The remaining portions of the dielectric material thus form dielectric layer 160.

Next, a backside interconnect structure including a dielectric layer 162 and metal pads 164 are formed. The respective process is illustrated as process 208 in the process flow 200 as shown in FIG. 14. The formation process may include depositing a metallic layer such as an aluminum layer, an aluminum copper layer, a nickel layer, a titanium layer, and/or the like, and then patterning the metallic layer and to form metal pads 164. Dielectric layer 162 is then deposited. Alternatively, dielectric layer 162 may be deposited first, followed by the formation of metal pads 164 in dielectric layer 162 through a damascene process. It is appreciated that although one metal layer (the layer of metal pads 164) is illustrated, the backside interconnect structure may include a plurality of metal layers for the backside routing of electrical signals/voltages.

Electrical connectors 166 are then formed. In accordance with some embodiments, electrical connectors 166 include metal pillars, solder regions, and/or the like. Electrical connectors 166 may include electrical connectors (power bumps) 166A and 166B, which are discussed in subsequent paragraphs.

In a subsequent process, the composite wafer 68 as shown in FIG. 4 may be singulated, for example, in a die-saw process, so that a plurality of identical packages 68′ are formed as discrete packages. The respective process is illustrated as process 210 in the process flow 200 as shown in FIG. 14. The wafers 20 and 120 in composite wafer 68 are also singulated into device dies 20′ and device dies 120′, respectively.

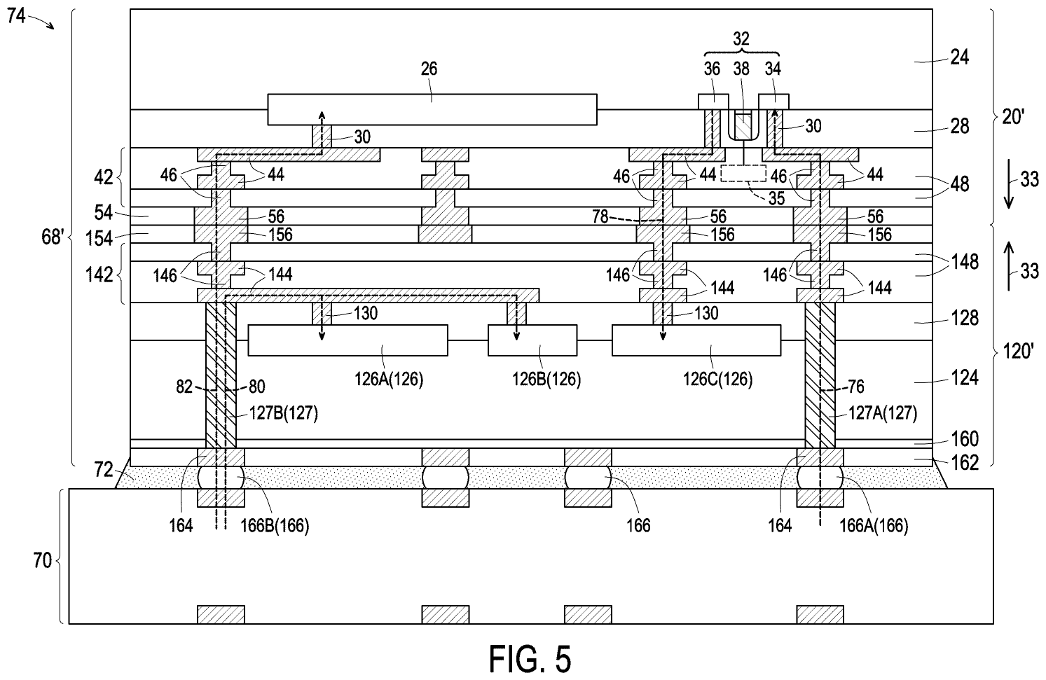

Referring to FIG. 5, in accordance with some embodiments, one of discrete packages 68′ is bonded to package component 70 to form package 74. The respective process is illustrated as process 212 in the process flow 200 as shown in FIG. 14. Package component 70 may be a package substrate, a silicon interposer, an organic interposer, a package with device die(s) therein, or the like. The bonding may be achieved through solder bonding, metal-to-metal direct bonding, or the like. Underfill 72 may then be dispensed between package 68′ and package component 70.

In package 74, electrical connector 166A may be used as a first power bump, and power is supplied from package component 70 to electrical connector 166A. The power is then supplied through electrical path 76, which includes through-via 127A, the metal lines 144 and vias 146 of device die 120′, and the metal lines 44 and vias 46 of device die 20′. The power (also referred to as ungated voltage TVDD) is thus provided to TVDD node 34.

When power switch 32 is turned on, the power is provided to VVDD node 36, and the corresponding voltage on VVDD node 36 (also referred to as gated voltage/power VVDD) is transferred back into device dies 120′ through electrical path 78, which includes the metal lines 44 and vias 46 of device die 20′, and the metal lines 144 and vias 146 of device die 120′. Integrated circuits 126C, which are also referred to as the power user circuits of the gated voltage VVDD, thus may receive the gated voltage VVDD when the power switch 32 is turned on. Integrated circuits 126C is cut from the power when the power switch 32 is turned off.

In accordance with some embodiments, by forming the power switch 32 in device die 20′ rather than in the device die 120′ in which the power user circuits 126C are located, the chip area of device die 120′ is saved. For example, device die 120′ may be a CPU die or a GPU die, which is demanding in chip area for its high-density of circuits. Furthermore, power switch 32 may occupy a large chip area, for example, up to 10 percent of the chip area of device die 120′. Accordingly, by moving the power switches to the less chip-area demanding device die 20′, the chip areas are used more efficiently. Furthermore, since the device density of device die 20′ is lower, the metal lines in device die 20′ may be formed wider and thicker, and the voltage drop of the power transfer paths in device die 20′ is low.

In accordance with some embodiments, power switch 32 is controlled by control circuit 35, which may provide control signals to the gate 38 of power switch 32 in order to control the on/off state of power switch 32. In accordance with some embodiments, the control circuit 35 may be located outside of device die 20′. For example, the control circuit 35 may include the integrate circuits 126B, which is physically located in device die 120′. Accordingly, control circuit 35 is illustrated as being dashed to indicate that it may not be physically located in device die 20′. When control circuit 35 comprises integrated circuit 126B, an additional signal path (not illustrated), which includes the metal lines 44 and vias 46 in device dies 20′, the metal lines 44 and vias 146 in device dies 120′, and bond pads 56 and 156, may electrical connect integrated circuit 126B to the gate 38 of power switch 32.

In accordance with some embodiments, a second power bump 166B is used to provide power to integrated circuits 126A through electrical path 80, which includes through-via 127B, metal lines 144, and contact plugs 130. Accordingly, device die 120′ includes integrated circuits 126A that are driven by ungated power (which may or may not have the ungated voltage TVDD), and integrated circuits 126C that are driven by the gated voltage VVDD. Also, integrated circuits 126B (the control circuit) may also be connected to the ungated power, for example, by connecting to power bump 166B, so that integrated circuits 126B may be able to generate the control signals for controlling power switch 32, even when power switch 32 is turned off.

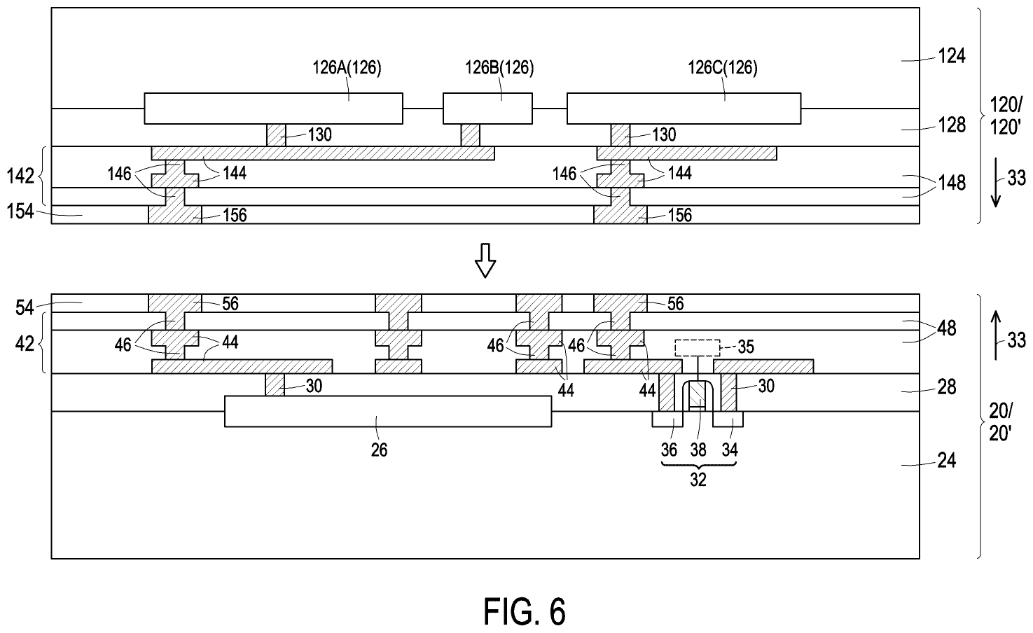

FIGS. 6 through 11 illustrate the cross-sectional views of intermediate stages in the formation of a package in accordance with alternative embodiments of the present disclosure. These embodiments are similar to the embodiments as shown in FIG. 1-5, except that device die 120′ (including the power user circuits) is a top die, and the device die 20′, which includes a power switch therein, is a bottom die. The bonding of device dies 20′ and 120′ is also through face-to-face bonding. Unless specified otherwise, the materials, the structures, and the formation processes of the components in these embodiments are essentially the same as the like components denoted by like reference numerals in the preceding embodiments. The details regarding the materials, the structures, and the formation processes provided in each of the embodiments throughout the description may be applied to any other embodiment whenever applicable.

In an initial process, wafers 20 and 120 are formed, as shown in FIG. 6. The materials, the structures, and the formation processes of wafer 20 and wafer 120 may be found referring to the discussion of the preceding embodiments. In accordance with these embodiments, however, opposite to the preceding embodiments, wafer 20 is at the bottom, and wafer 120 is at top. In accordance with some embodiments, through-vias may be formed using a through-via-last process, and no through-vias are formed at this time. In accordance with alternative embodiments, through-vias may also be formed through a through-via-first process, and through-vias may be formed in wafer 20 at this time. The corresponding formation process of through-vias in wafer 120 using through-via-first process may be similar to what is shown in FIGS. 2 through 4.

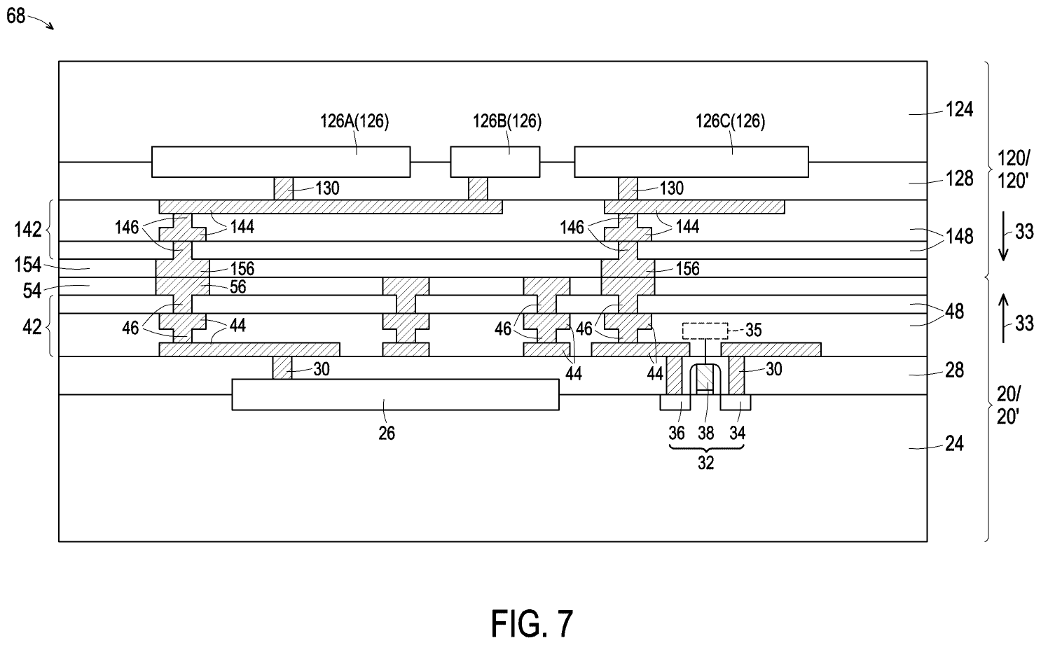

Next, referring to FIG. 7, wafer 120 is bonded to wafer 20, for example, through hybrid bonding, while other applicable bonding schemes may also be adopted. Composite wafer 68 is thus formed.

Referring to FIG. 8, a backside thinning process is performed, so that semiconductor substrate 24 is thinned. Subsequently, as shown in FIG. 9, dielectric layer 60 is formed on the backside of semiconductor substrate 24, and through-vias 27 are formed to penetrate through dielectric layer 60 and semiconductor substrate 24.

In accordance with some embodiments, the formation of through-vias 27 includes depositing dielectric layer 60 on the backside of the semiconductor substrate 24, and etching the dielectric layer 60 and semiconductor substrate 24 to form deep openings. Metal lines 44 (metal pads) are exposed to the deep openings. Next, a dielectric liner (not shown) is deposited in a conformal deposition process and extending into the openings, followed by an anisotropic etching process, so that the horizontal portions of the dielectric liner are removed, and vertical portions are left as the dielectric liner. The metal pads of metal lines 44 are revealed again. The deep openings are then filled with conductive materials to form through-vias 27.

In accordance with alternative embodiments, the formation of through-vias 27 includes etching semiconductor substrate 24 to form deep openings, forming dielectric liners lining the deep openings, and forming the through-vias 27 in the openings and encircled by the dielectric liners. The semiconductor substrate 24 may then be recessed, so that some end portions of through-vias 27 protrude out of the recessed semiconductor substrate 24. Dielectric layer 60 is then formed. Dielectric layer 60 may also be formed of silicon oxide, silicon nitride, silicon oxynitride, and the like.

Next, a backside interconnect structure including metal pads 64 and dielectric layer 62 are formed, with metal pads 64 connected to through-vias 27. The materials and the formation processes of metal pads 64 and dielectric layer 62 may be essentially the same as metal pads 164 and dielectric layer 162, respectively in FIG. 4. The details are thus not repeated herein. Electrical connectors 166 are then formed. Electrical connectors 166 may be essentially the same as in the preceding embodiments.

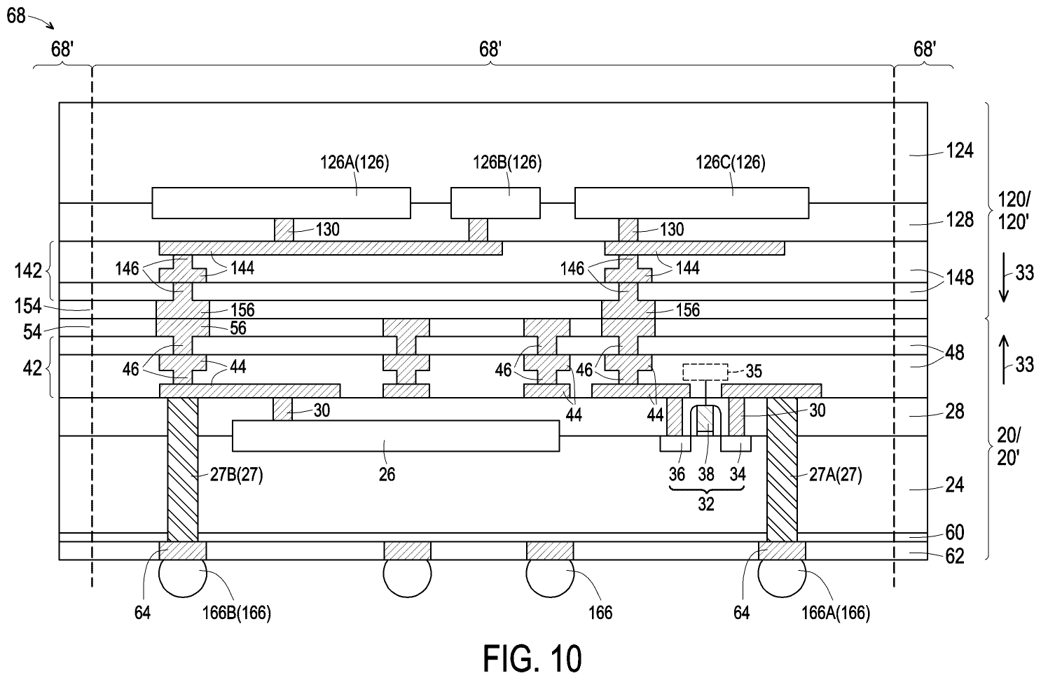

In a subsequent process, the composite wafer 68 as shown in FIG. 10 may be singulated, for example, in sawing process, so that a plurality of discrete packages 68′ are formed. Wafers 20 and 120 are also singulated into device dies 20′ and 120′, respectively.

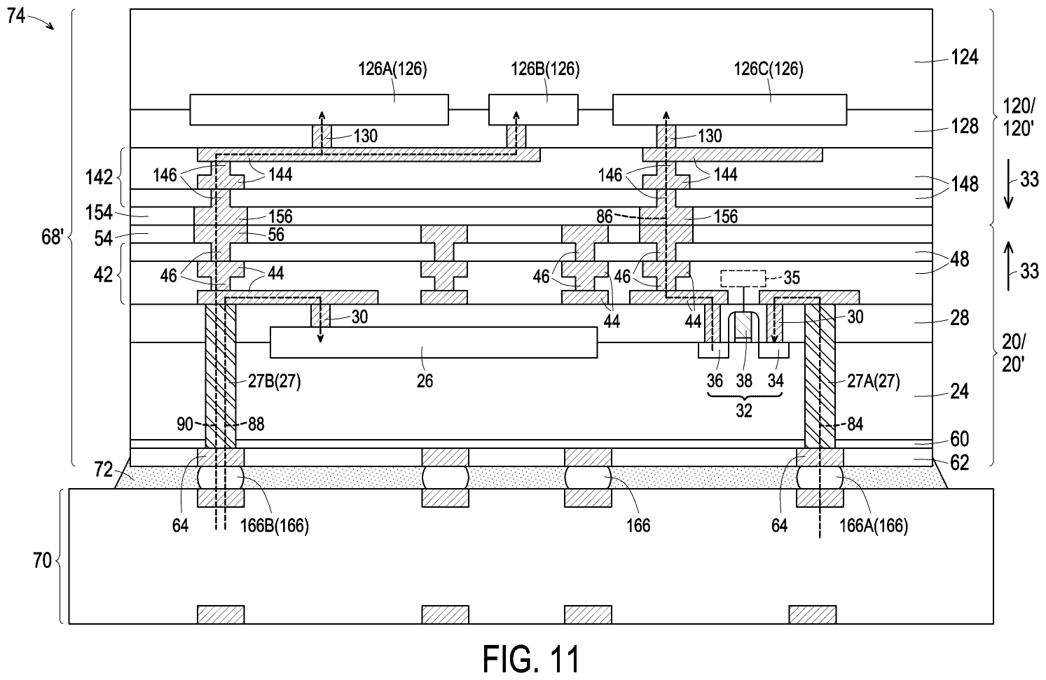

Referring to FIG. 11, one of discrete packages 68′ is bonded to package component 70, which may be a package substrate, an interposer (such as a silicon interposer or an organic interposer), a package with device die(s) therein, or the like. Package 74 is thus formed. The bonding may be achieved through solder bonding, metal-to-metal direct bonding, or the like. Underfill 72 may then be dispensed between package 68′ and package component 70.

In package 74, electrical connector 166A may be used as a first power bump, and power is supplied from package component 70 to electrical connector 166A. The power is then supplied through electrical path 84, which includes through-via 27A, metal line(s) 44, and contact plugs 30. The ungated voltage TVDD is thus supplied to TVDD node 34, which may be the source region of the power switch 32. When power switch 32 is turned on, the power is provided to VVDD node 36, and the gated voltage VVDD is provided to integrated circuits 126C through electrical path 86. Electrical path 86 includes the metal lines 44 and vias 46 of device die 20′, and the metal lines 144 and vias 146 of device die 120′. Integrated circuits 126C, which are also referred to as the power user circuits that are powered by the gated voltage VVDD, thus may receive the gated voltage VVDD when the power switch 32 is turned on, and is cut off from the power when the power switch 32 is turned off.

In accordance with some embodiments, by forming the power switch 32 in device die 20′ rather than the device die 120′ in which the power user circuits 126C are located, the chip area of device die 120′ is saved.

In accordance with some embodiments, power switch 32 is located in device die 20′, and is controlled by control circuit 35, which may provide control signals to the gate 38 of power switch 32 and to control the on/off state of power switch 32. In accordance with some embodiments, the control circuit 35 may be located outside of device die 20′. For example, the control circuit 35 may include the integrate circuits 126B, which is physically located in device die 120′. Accordingly, control circuit 35 is illustrated as being dashed to indicate that it may not be (or may be) physically located in device die 20′. When control circuit 35 comprises integrated circuit 126B, an additional signal path (not shown) may electrical connect integrated circuit 126B to the gate 38 of power switch 32.

In accordance with some embodiments, a second power bump 166B is used to provide power to integrated circuits 26 through electrical path 88, which includes through-via 27B. Furthermore, device die 120′ includes integrated circuits 126A that receive ungated power through electrical path 90, which includes the through-via 27B, the metal lines 44 and vias 46 of device die 20′, and the metal lines 144 and vias 146 of device die 120′. The integrated circuits 126A are driven by ungated power. Also, integrated circuits 126B (the control circuit) may also be connected to the ungated power, for example, by connecting to power bump 166B, so that integrated circuits 126B may be able to generate the signals for controlling power switch 32 when power switch 32 is turned off.

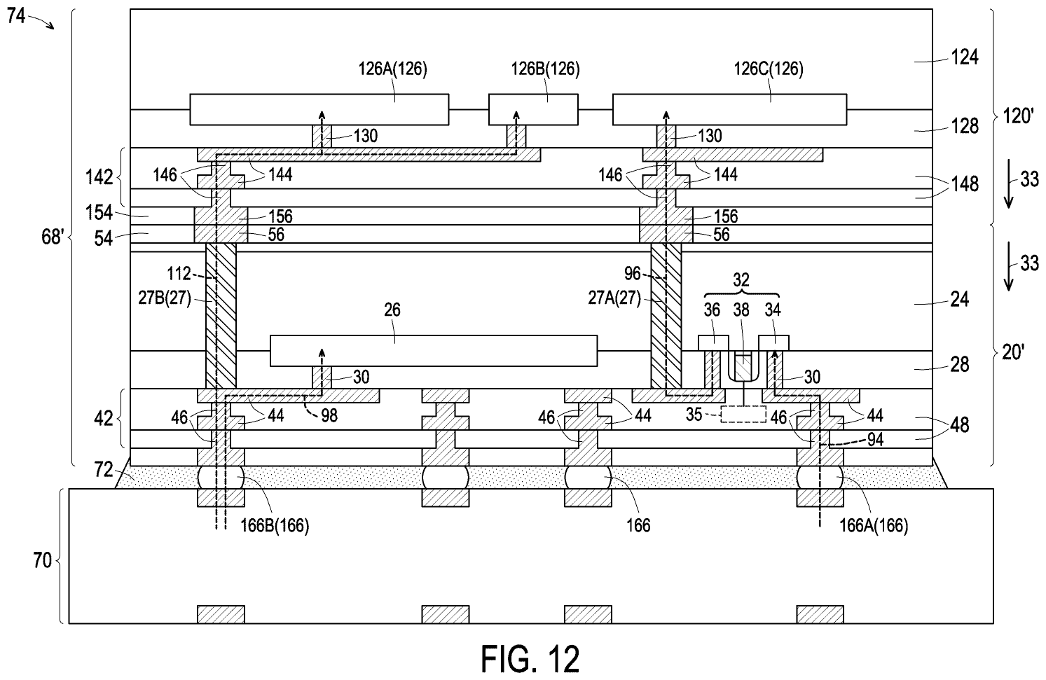

FIG. 12 illustrates package 74 formed in accordance with yet alternative embodiments. FIG. 12 illustrates a package formed through a face-to-back bonding scheme, wherein the front side of device die 120′ faces the backside of device die 20′. The arrows 33 on the right side of FIG. 12 represent the facing directions of wafers 20 (and device dies 20′) and 120 (and device dies 120′). Also, in package 74, the device die 20′, in which power switch 32 is located, is located at bottom, while device die 120′, which includes the power user circuits of the gated power is at top. The formation of the package 74 in FIG. 12 may be realized through the discussion of the formation processes as shown in FIGS. 1 through 11.

In package 74, electrical connector 166A may be used as a first power bump, and power is supplied from package component 70 to electrical connector 166A. The power is then supplied through electrical path 94, which includes the metal lines 44 and vias 46 in device die 20′, and contact plug 30. The power is supplied to TVDD node 34, which may be the source region of the power switch 32. When power switch 32 is turned on, the gated power is provided to VVDD node 36. The gated voltage VVDD may be provided to device die 120′ through electrical path 96. Electrical path 96 includes the metal lines 44 and vias 46 of device die 20′, through-via 27A, bond pads, and the metal lines 144 and vias 146 of device die 120′. Integrated circuits 126C, which are also the power user circuits of the gated voltage VVDD, thus may receive the gated voltage VVDD when the power switch 32 is turned on, and is cut from the power when the power switch 32 is turned off.

In accordance with some embodiments, power switch 32 is located in device die 20′, and may be controlled by control circuit 35 (such as integrated circuits 126B), which may provide control signals to the gate 38 of power switch 32 and to control the on/off state of power switch 32. In accordance with some embodiments, the control circuit 35 may be located outside of device die 20′. For example, the control circuit 35 may include the integrate circuits 126B, which is physically located in device die 120′. Accordingly, control circuit 35 is illustrated as being dashed to indicate that it may not be (or may be) physically located in device die 20′. When control circuit 35 comprises integrated circuit 126B, an additional signal path may electrical connect integrated circuit 126B to the gate 38 of power switch 32.

In accordance with some embodiments, a second power bump 166B is used to provide power to integrated circuits 26 through electrical path 98, which includes the metal lines 44 and vias 46 of device die 20′, and contact plugs 30. Furthermore, device die 120′ includes integrated circuits 126A that receive power through electrical path 112, which includes the through-via 27B, the metal lines 144 and vias 146 of device die 120′, the metal lines 44 and vias 46 of device die 20′, and bond pads 56 and 156. The integrated circuits 126A are driven by ungated power. Also, integrated circuits 126B (the control circuit) may also be connected to the ungated voltage, for example, by connecting to power bump 166B, so that integrated circuits 126B may be able to generate the signals for controlling power switch 32 when power switch 32 is turned off.

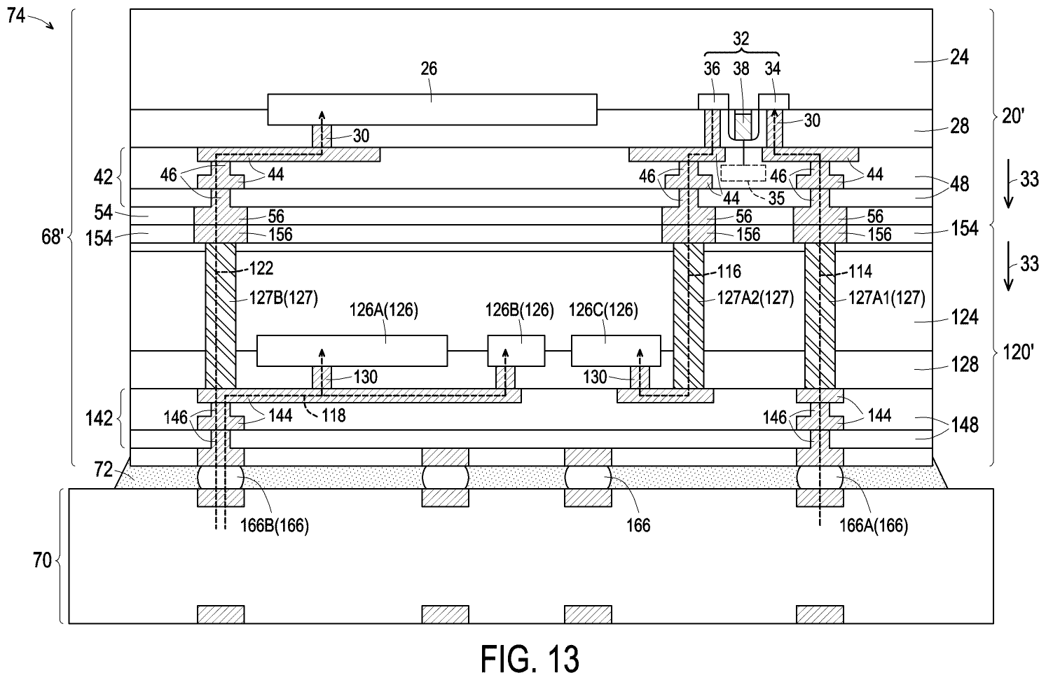

FIG. 13 illustrates package 74 formed in accordance with alternative embodiments. FIG. 13 also illustrates a package formed through a face-to-back bonding scheme, wherein the front side of device die 20′ faces the backside of device die 120′. The arrows 33 on the right side of FIG. 13 represent the facing directions of wafers 20 (and device dies 20′) and 120 (and device dies 120′). Also, in package 74, the device die 20′, in which power switch 32 is located, is located at top, while device die 120′, which includes the power user circuits 126C of the gated voltage VVDD is at bottom. The formation of the package 74 in FIG. 13 may be realized through the discussion of the formation processes as shown in FIGS. 1 through 11.

In package 74, electrical connector 166A may be used as a first power bump, and power is supplied from package component 70 to electrical connector 166A. The power is then supplied through electrical path 114, which includes the metal lines 144 and vias 146 in device die 120′, through-via 127A1, and the metal lines 44 and vias 46 in device die 20′. The power is supplied to TVDD node 34, which may be the source region of the power switch 32. When power switch 32 is turned on, the gated power is provided to VVDD node 36.

The gated voltage VVDD may be provided to device die 120′ through electrical path 116. Electrical path 116 includes the metal line 44 and vias 46 of device die 20′, through-via 127A2, and bond pads 56 and 156. Accordingly, in accordance with these embodiments, power was passed through two through-vias 127A1 and 127A2 before the gated power is provided to integrated circuits 126C.

In accordance with some embodiments, a second power bump 166B is used to provide power to integrated circuits 126A and 126B through electrical path 118, which includes the metal lines 144 and vias 146 of device die 120′ and the metal lines 44 and vias 46 in device die 20′. Device die 20′ includes integrated circuits 26 that receive power through electrical path 122, which includes the metal lines 144 and vias 146 of device die 120′, the through-via 127B, and the metal lines 44 and vias 46 of device die 20′. The integrated circuits 26 are driven by the ungated power. Also, integrated circuits 126B (the control circuit) may also be connected to the ungated power, for example, by connecting to power bump 166B, so that integrated circuits 126B may be able to generate the signal for controlling power switch 32 when power switch 32 is turned off.

In above-illustrated embodiments, some processes and features are discussed in accordance with some embodiments of the present disclosure to form a three-dimensional (3D) package. Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

The embodiments of the present disclosure have some advantageous features. By forming power switches outside of the advanced device die that has the power user circuits, which use the gated power, the chip area that otherwise will be occupied by the chip-area-demanding power switches is saved. The power switch is moved to a less-advanced device die, which has more room for allocating the power switch. Also, since the metal lines in the less-advanced device die may be thick and wide, the voltage drop in the less-advanced device die is low.

In accordance with some embodiments of the present disclosure, a method comprises forming a first device die comprising a first integrated circuit; a first bond pad at a first surface of the first device die, wherein the first integrated circuit is electrically connected to the first bond pad; forming a second device die comprising a power switch comprising a first source/drain region; a second source/drain region; a second bond pad electrically connecting to the first source/drain region; and a third bond pad electrically connecting to the second source/drain region; bonding the first device die with the second device die to form a first package, with the first bond pad bonding to the third bond pad; and bonding the first package to a package component.

In an embodiment, the forming the first device die further comprises forming a through-via penetrating through a semiconductor substrate of the first device die, wherein after the first device die is bonded with the second device die, the through-via is electrically coupled to the first source/drain region. In an embodiment, the through-via is formed before the first device die is bonded with the second device die. In an embodiment, the through-via is formed after the first device die is bonded with the second device die. In an embodiment, the first device die is bonded between the second device die and the package component.

In an embodiment, the first device die is bonded to the package component through a power bump that receives an ungated voltage from the package component, and is connected to the first integrated circuit through an electrical path, and wherein the electrical path comprises a first part from the power bump to the power switch; and a second part from the power switch to the first integrated circuit. In an embodiment, the first device die is bonded with the second device die through face-to-face bonding.

In an embodiment, the first device die is bonded with the second device die through face-to-back bonding. In an embodiment, the second device die is bonded between the first device die and the package component. In an embodiment, the first device die further comprises a second integrated circuit, wherein the second integrated circuit is configured to receive power when the first integrated circuit is cut from power by the power switch.

In accordance with some embodiments of the present disclosure, a structure comprises a first device die comprising a first integrated circuit; and a second device die comprising a power switch electrically connecting to the first integrated circuit, wherein the power switch is configured to cut off power to the first integrated circuit in response to a first control signal; and provide power to the first integrated circuit in response to a second control signal. In an embodiment, the first device die comprises a logic die, and the second device die comprises an input/output die or a memory die. In an embodiment, the structure further comprises a control circuit configured to provide the first control signal and the second control signal, wherein the control circuit is outside of the first device die.

In an embodiment, the control circuit is in the second device die. In an embodiment, the first device die is bonded to the second device die through face-to-face bonding. In an embodiment, the first device die is bonded to the second device die with face-to-back bonding. In an embodiment, a power supplying path for supplying power to the first integrated circuit comprises a first part penetrating through the first device die to reach the power switch; and a second part have a first portion in the first device die, and a second portion in the second device die. In an embodiment, the first device die further comprises a second integrated circuit, wherein a power supplying path for supplying power to the second integrated circuit is decoupled from the power switch.

In accordance with some embodiments of the present disclosure, a structure comprises a package substrate; a first device die over and bonding to the package substrate, wherein the first device die comprises a semiconductor substrate; an integrated circuit on the semiconductor substrate; a through-via penetrating through the semiconductor substrate; and a second device die over and bonding to the first device die, wherein the second device die comprises a power switch, and wherein the power switch comprises a first source/drain region electrically connecting to the through-via in the first device die; and a second source/drain region connecting to the integrated circuit in the first device die. In an embodiment, the power switch is configured to cut off or provide power to the integrated circuit in response to different control signals that control operations of the power switch.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a first device die comprising:
a first integrated circuit;
a first bond pad at a first surface of the first device die, wherein the first integrated circuit is electrically connected to the first bond pad;
forming a second device die comprising:
a power switch comprising:
a first source/drain region;
a second source/drain region;
a second bond pad electrically connecting to the first source/drain region; and
a third bond pad electrically connecting to the second source/drain region;
bonding the first device die with the second device die to form a first package, with the first bond pad bonding to the third bond pad;
bonding the first package to a package component; and
forming the first device die further comprises forming a through-via penetrating through a semiconductor substrate of the first device die, wherein after the first device die is bonded with the second device die, the through-via is electrically coupled to the first source/drain region, and wherein the first device die is bonded between the second device die and the package component.
